(19) United States
(12) Patent Application Publication
(10) Pub. No.: US 2017/0253958 A1
(43) Pub. Date: Sep. 7, 2017

(54) DEPOSITION APPARATUS AND METHOD OF MANUFACTURING DISPLAY DEVICE USING THE SAME

(71) Applicant: SAMSUNG DISPLAY CO., LTD., Yongin-si (KR)

(72) Inventors: Sok Won NOH, Suwon-si (KR); Do Young KIM, Hwaseong-si (KR); Kook Chol PARK, Hwaseong-si (KR); Zin Seok YOON, Seoul (KR)

(21) Appl. No.: 15/267,399

(22) Filed: Sep. 16, 2016

(30) Foreign Application Priority Data
Mar. 7, 2016 (KR) 10-2016-0027193

(51) Int. Cl. C23C 14/24; C23C 14/54

(52) U.S. Cl. CPC C23C 14/243; C23C 14/54; G02F 1/1333

(57) ABSTRACT

A method of manufacturing a display device includes providing a deposition source and a substrate facing each other, the deposition source including a rotating rod, an internal module engaged with the rotating rod and having a storage unit for storing a deposition material, and an external housing covering the rotating rod and the internal module and having an outlet communicating with ambient air, rotating the rotating rod in the deposition source, such that the internal module engaged with the rotating rod is rotated, and applying the deposition material discharged through the outlet of the external housing onto the substrate.

### CROSS-REFERENCE TO RELATED APPLICATION

Korean Patent Application No. 10-2016-0027193, filed on Mar. 7, 2016, in the Korean Intellectual Property Office, and entitled: “Deposition Apparatus and Method of Manufacturing Display Device Using the Same,” is incorporated by reference herein in its entirety.

### BACKGROUND

1. Field

The present disclosure relates to a deposition apparatus and a method of manufacturing a display device using the same.

2. Description of the Related Art

With the development of multimedia, the importance of a display device has increased. Therefore, various kinds of display devices, e.g., liquid crystal displays (LCDs) and organic light emitting diode (OLED) displays, are used.

A display device may be manufactured by laminating various kinds of thin films on a substrate. One of the methods of forming a thin film on a substrate includes forming a thin film by evaporating a film-forming material and applying the evaporated film-forming material onto a substrate.

### SUMMARY

An aspect of the present disclosure provides a deposition apparatus, in which the straightness of a deposition material is excellent.

Another aspect of the present disclosure provides a deposition apparatus, in which the transfer rate of a deposition material is excellent.

Still another aspect of the present disclosure provides a method of manufacturing a display device using the deposition apparatus.

According to an aspect of the present disclosure, there is provided a deposition apparatus, including a rotating rod, an internal module engaged with the rotating rod and including a storage unit for storing a deposition material, and an external housing covering the rotating rod and the internal module and having an outlet communicated with ambient air.

The external housing may have a cylindrical shape.

The external housing and the rotating rod may be rotatably engaged with each other.

The deposition apparatus may further include a guide panel disposed at least one side of the outlet.

The internal module may include a first rotation plate and a second rotating plate, which are disposed to be spaced apart from each other at a predetermined interval.

The deposition apparatus may further include a rotation support disposed between the first rotation plate and the second rotation plate.

The internal module further may include a side wall extended in a direction parallel to the rotating rod and an upper cover bended and extended from one end of the side wall.

The end of the upper cover may be spaced apart from the rotation support at a predetermined interval.

The internal module may include a partition, and the deposition material may be stored in a space defined by the partition.

The partition may include a side wall extended in a direction parallel to the rotating rod and an upper cover bended and extended from one end of the side wall.

A plurality of internal modules may be provided, and the plurality of internal modules may be superimposed along the length direction of the rotating rod.

The plurality of internal modules may include a first internal module and a second internal module, the first internal module may store a first deposition material, and the second internal module may store a second deposition material different from the first deposition material.

The external housing may include a plurality of outlets, and the plurality of outlets may have opening directions different from each other.

According to another aspect of the present disclosure, there is provided a deposition apparatus, including a rotating rod rotated clockwise or counterclockwise, an internal module including a storage unit for storing a deposition material and engaged with the rotating rod to be rotated in the same direction as the rotating rod, and an external housing covering the rotating rod and the internal module and having an outlet for discharging the deposition material.

Centrifugal force may be provided to the deposition material by the rotation of the internal module.

A plurality of internal modules may be provided, and the plurality of internal modules may be rotated in the same direction as the rotating rod.

The plurality of internal modules may include a first internal module and a second internal module, and the first internal module and the second internal module may be rotated at different speeds from each other.

According to still another aspect of the present disclosure, there is provided a method of manufacturing a display device, including providing a deposition source and a substrate facing the deposition source, the deposition source including a rotating rod, an internal module engaged with the rotating rod and including a storage unit for storing a deposition material, and an external housing covering the rotating rod and the internal module and having an outlet communicated with ambient air, rotating the rotating rod to rotate the internal module engaged with the rotating rod, and applying the deposition material discharged through the outlet of the external housing onto the substrate.

Centrifugal force may be provided to the deposition material by the rotation of the internal module.

A plurality of internal modules may be provided, and the plurality of internal modules may be rotated in the same direction as the rotating rod.

According to yet another aspect of the present disclosure, there is provided a deposition apparatus including a rotating rod, an internal module engaged with the rotating rod, the internal module including a storage unit for storing a deposition material, and an external housing accommodating the rotating rod and the internal module, the external housing including an outlet facing a deposition target, and the rotating rod and internal module being rotatable within the external housing.

An opening of the storage unit may be concentric with the rotating rod, the storage unit being rotatable together with the rotating rod.

The internal module may further include a side wall extended in a direction parallel to the rotating rod and an upper cover bent from the sidewall toward the rotating rod, the side wall and the upper cover defining the storage unit around the rotating rod, and the opening of the storage unit being defined between an edge of the upper cover and the rotating rod.

An interior of the storage unit may be in fluid communication with an exterior of the storage unit through the opening.

The rotating rod and internal module may be rotatable together in a same direction.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic layout view of a deposition apparatus according to an embodiment;

FIG. 2 illustrates an enlarged view of a configuration of FIG. 1;

FIG. 3 illustrates a sectional perspective view of FIG. 2;

FIG. 4 illustrates an enlarged view of a configuration of FIG. 3;

FIG. 5 illustrates a sectional view taken along line I-I′ of FIG. 4;

FIG. 6 illustrates a sectional perspective view of a deposition apparatus according to an embodiment;

FIG. 7 illustrates a perspective view of a deposition apparatus according to an embodiment;

FIG. 8 illustrates a cross-sectional view of a deposition apparatus according to an embodiment;

FIG. 9 illustrates a sectional perspective view of a deposition apparatus according to another embodiment;

FIG. 10 illustrates a longitudinal sectional view of the deposition apparatus of FIG. 9;

FIG. 11 illustrates a cross-sectional view of a deposition apparatus according to another embodiment;

FIG. 12 illustrates a cross-sectional view of a deposition apparatus according to still another embodiment;

FIG. 13 illustrates a cross-sectional view of a deposition apparatus according to still another embodiment; and

FIG. 14 illustrates a cross-sectional view of a deposition apparatus according to still another embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer (or element) is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

Although the terms “first, second, and so forth” are used to describe diverse constituent elements, such constituent elements are not limited by the terms. The terms are used only to discriminate a constituent element from other constituent elements. Accordingly, in the following description, a first constituent element may be a second constituent element.

Hereinafter, preferred embodiments will be described in detail with reference to the attached drawings.

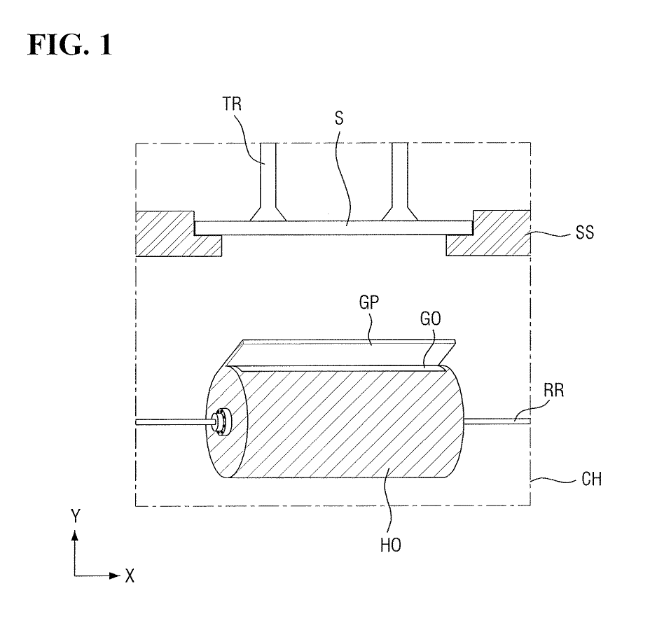

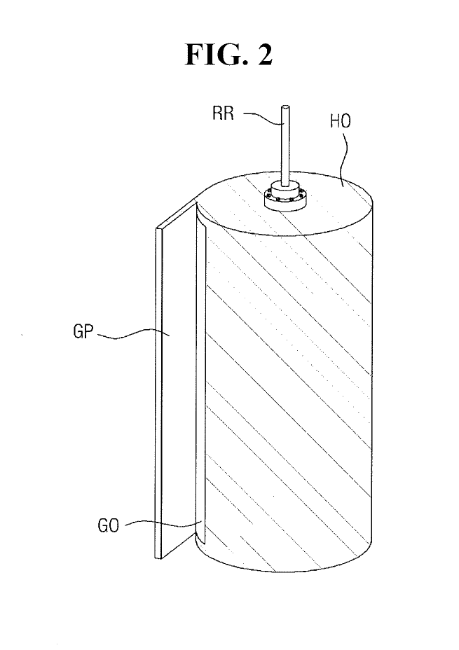

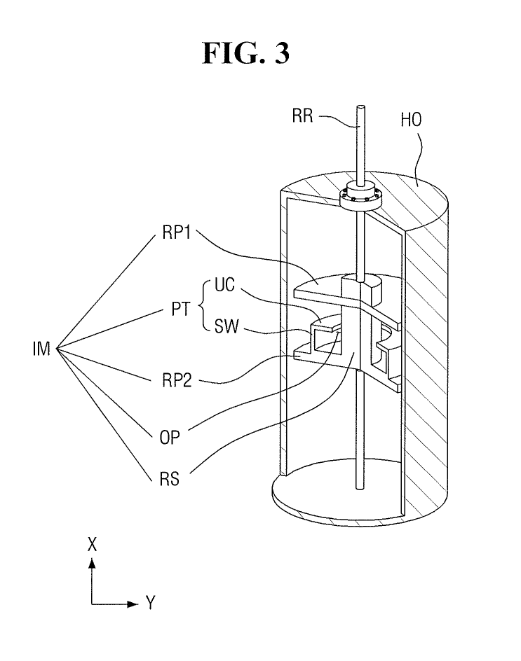

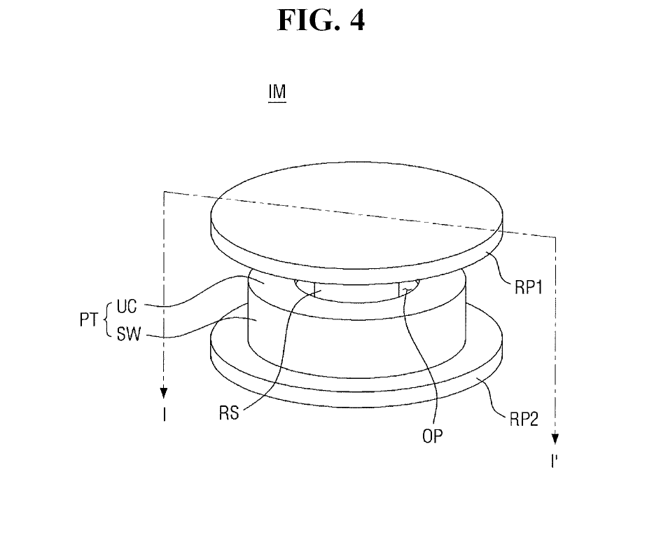

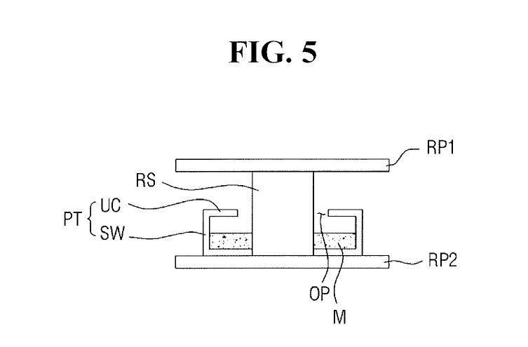

FIG. 1 is a schematic layout view of a deposition apparatus according to an embodiment, FIG. 2 is an enlarged view for illustrating a configuration of FIG. 1, FIG. 3 is a sectional perspective view of FIG. 2, FIG. 4 is an enlarged view for illustrating a configuration of FIG. 3, and FIG. 5 is a sectional view taken along line I-I′ of FIG. 4.

Referring to FIGS. 1 to 5, a deposition apparatus according to an embodiment may include a rotating rod RR, an internal module IM engaged with the rotating rod RR and including a storage unit for storing a deposition material, and an external housing HO covering the rotating rod RR and the internal module IM and having an outlet GO communicating with ambient air.

The deposition apparatus according to an embodiment may include a chamber CH. The chamber CH may have an inner space of a predetermined size. That is, the chamber CH may provide a space in which various configurations to be described later are arranged. The inner space of the chamber CH may be blocked with the outer space of the chamber CH, i.e., the inner space of the chamber CH may be a sealed space defined by sidewalls of the chamber CH. In other words, the inner space and outer space of the chamber CH are separated from each other, e.g., by the sidewalls of the chamber CH, and the flow of air may be cut off therebetween. However, the chamber CH is not designed to be always sealed, and may be designed to enable the switching of the chamber CH between a sealing mode and a ventilation mode by additionally forming an inlet and an outlet. FIG. 1 illustrates a case of the inner space of the chamber CH having a rectangular parallelepiped shape, but the shape of the inner space of the chamber CH is not limited thereto.

A deposition source may be disposed in the camber CH. The deposition source serves to transfer a deposition material to a substrate S to be described later. The deposition source may include the rotating rode RR, the internal module IM, the external housing HO, and a guide panel GP.

The rotating rod RR may extend in a length direction, e.g., along the x-axis in FIG. 1. In detail, the rotating rod RR may have a bar shape extending in a length direction. The rotation axis of the rotating rod RR may be parallel to the length direction. That is, the rotating rod RR may be rotated clockwise or counterclockwise about the rotation axis parallel to the length direction.

In order to rotate the rotating rod RR, at least one end of the rotating rod RR may be connected with a drive unit for the rotating rod RR. The drive unit may serve to provide a rotation force to the rotating rod RR. The type of the drive unit for the rotating rod RR may be any suitable driver, e.g., a machine capable of providing a rotational force to a bar-shaped rod can be generally used as the driving unit. For example, the drive unit may be a motor or an actuator.

At least one end of the rotating rode RR may be rotatably engaged with the inner wall of the chamber CH. Here, the “at least one end of the rotating rode RR being rotatably engaged” means that at least one end of the rotating rode RR is engaged to be rotated in a state of being fixed.

In another embodiment, the rotating rod RR may be horizontally moved along the inner wall of the chamber CH. When the rotating rod RR is engaged with the inner wall of the chamber CH to be horizontally moved, the entire deposition source can be horizontally moved along the rotating rod RR.

In still another embodiment, the rotating rod RR can be vertically moved along the inner wall of the chamber CH. When the rotating rod RR is vertically moved along the inner wall of the chamber CH, the entire deposition source can be vertically moved along the rotating rod RR.

The rotating rod RR may be made of a metal material. However, the present disclosure is not limited thereto, and any suitable material having a strength necessary for supporting the deposition source may be used as the material of the rotating rod RR.

The external housing HO may be disposed to cover at least a part of the rotating rod RR. For example, the external housing HO may have a cylindrical shape. For example, the external housing HO may have a cylindrical shape extending in the same direction as the length direction of the rotating rod RR, e.g., along the x-axis in FIG. 1. Further, the external housing HO may be rotatably engaged with the rotating rod RR. The meaning of the external housing HO being rotatably engaged is the same as the aforementioned meaning. That is, when the rotating rod RR is rotated, the external housing OH may be fixed without being rotated. In other words, even when the rotating rod RR disposed in the external housing HO is rotated, the external housing OH covering the rotating rod RR may be fixed at the original position thereof, and may not be rotated.

The internal module IM may be disposed in the external housing HO. The internal module IM may include a storage unit for storing a deposition material. A detailed explanation thereof will be described with reference to FIGS. 3 to 5.

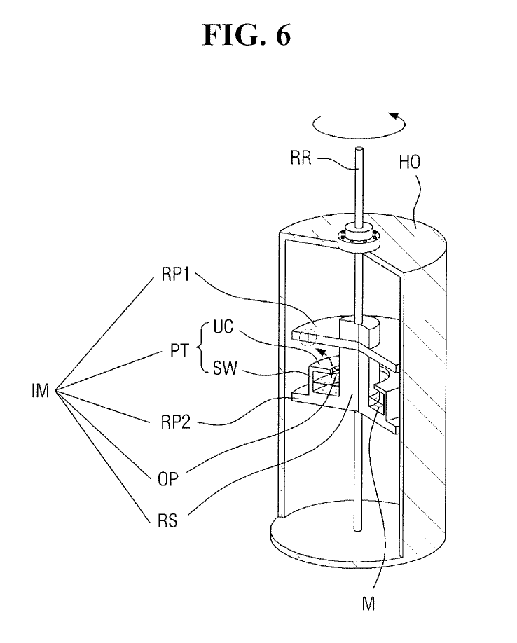

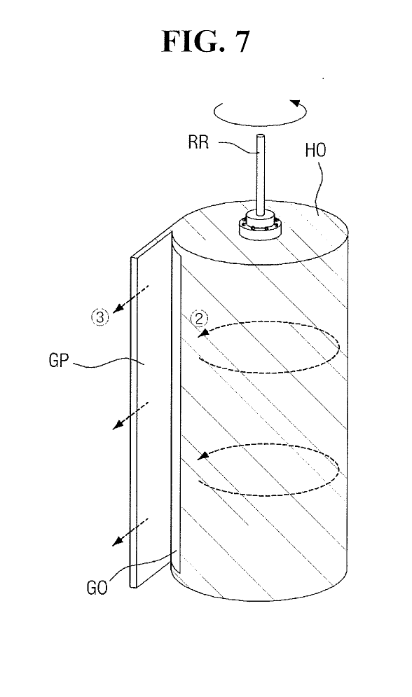

The external housing HO may include an outlet GO. The outlet GO may communicate between the inside and outside of the external housing HO, e.g., the outlet GO may provide fluid communication between the inside and outside of the external housing HO. That is, the outlet GO of the external housing HO may be an opening. As will be explained later, the external housing 110 may be filled with a gaseous deposition material, e.g., a film-forming material, and the gaseous deposition material may be discharged into the chamber CH through the outlet GO. A detailed explanation of the operation of this deposition apparatus will be described later with reference to FIGS. 6 and 7.

The guide panel GP may be disposed at least at one side of the outlet GO. The guide panel GP may guide the, e.g., direction of, movement of the deposition material discharged from the outlet GO. In other words, the guide panel GP guides the deposition material discharged from the outlet GO, so as to induce the movement of the deposition material toward the substrate S, rather than toward the sidewall of the chamber CH.

The substrate S may be disposed to face the deposition source. The substrate S may be provided with various elements. In order to form a thin film having a specific pattern, various masks may be disposed between the substrate S and the deposition source. However, a configuration related to the mask is omitted in order to clearly define the scope of embodiments.

The substrate S may be supported by a substrate support SS for supporting the edge of the substrate S. The substrate support SS may support the edge of the substrate S, and may expose the center of the substrate S. For example, the outlet GO of the external housing HO may be oriented to face and overlap the exposed center of the substrate S. Thus, the film-forming material provided from the deposition source, e.g., released from the outlet GO of the external housing HO, reaches the center of the substrate S, so as to form a thin film thereon.

The chamber CH may further include a transportation unit TR for moving the substrate S. For example, the transportation unit TR may be configured to include a robot arm or various chucks. However, the present disclosure is not limited thereto, e.g., the transportation unit TR may include all types of transportation units that can take out and draw the substrate S.

The substrate S may be moved horizontally or vertically by the transportation unit TR. That is, as described above, the deposition source and/or the substrate S can be moved vertically and/or horizontally in order to form a uniform thin film on the substrate S.

FIG. 1 illustrates a case of the length direction of the rotating rod RR being perpendicular to the gravity direction, i.e., along the x-axis in FIG. 1, but the length direction of the rotating rod RR is not limited thereto. In another embodiment, the length direction of the rotating rod RR may be the same as the gravity direction. In this case, the rotating rod RR may be disposed in the chamber CH in a direction perpendicular to the lower surface of the chamber CH. When the rotating rod RR is disposed in the chamber CH in the gravity direction, the substrate S, in correspondence to the rotating rod RR, may also be disposed in a direction perpendicular to the lower surface of the chamber CH.

Hereinafter, the external housing HO will be described with reference to FIG. 2.

The external housing HO may have a cylindrical or columnar shape. The external housing HO may have a cylindrical or columnar shape, and may extend in the same direction as the length direction of the rotating rod RR. The external housing HO may be disposed to cover at least a part of the rotating rode RR. That is, as shown in FIG. 2, at least a part of the rotating rode RR may be disposed in, e.g., inside, the external housing HO. The rotating rode RR disposed in the external housing HO may be engaged with the internal module IM to be described later.

The rotating rod RR may be rotatably engaged with one end and/or the other end of the external housing 110. That is, even when the rotating rod RR is rotated, the external housing may be fixed without being rotated.

In an embodiment of the external housing HO having a cylindrical shape, the external housing HO may include top and bottom surfaces facing each other, and a lateral surface connecting these top and bottom surfaces. In this case, the rotating rod RR may be engaged with central portions of the top and bottom surfaces. In order to rotatably engage the rotating rod RR, the top and bottom surfaces may have insert holes, respectively. That is, the rotating rod RR is inserted into the insert holes respectively formed in the top and bottom surfaces to support the external housing HO.

The external housing HO may be made of a metal material. However, the present disclosure is not limited thereto, and any suitable materials capable of maintaining sufficient strength to replace the metal material, e.g., engineering plastics, may be used as the material of the external housing HO.

The outlet GO may be disposed at one side of the external housing HO. The outlet GO may extend in a length direction of the external housing HO, e.g., along the x-axis.

The inner space of the external housing HO can communicate with ambient air through the outlet GO. That is, as will be described later, the external housing HO may be filled with a gaseous deposition material, and the gaseous deposition material may be discharged from the external housing HO into the chamber CH through the outlet GO.

The guide panel GP may be disposed at least at one side of the outlet GO. The guide panel GP can guide the movement of the deposition material discharged from the outlet GO. In detail, the guide panel GP guides the deposition material discharged from the outlet GO such that the deposition material moves toward the substrate S. The guide panel GP may have a plate shape. The guide panel GP may extend in parallel to one side of the outlet GO, and the extending length thereof may be substantially equal to the length of the outlet GO. The guide panel GP may be disposed to face the substrate S. As such, when the guide panel GP is disposed to face the substrate S, the guide panel GP guides the deposition material discharged from the outlet GO such that this deposition material moves toward the substrate S, so as to prevent the deposition material from moving toward the inner wall of the chamber CH.

FIG. 2 illustrates a case of the guide panel GP being formed at only one side of the outlet GO, but the present disclosure is not limited thereto. The guide panels GP may be disposed at both sides of the outlet GO. In this case, the movement direction of the deposition material discharged from the outlet GO is further restricted, and thus the straightness, e.g., uniformity, of the deposition material can be improved.

Although not shown in the drawings, a heater for heating the deposition material M (FIG. 5) may be disposed inside and/or outside the external housing HO. The heater serves to vaporize the solid or liquid deposition material M by heating the deposition material M. The position of the heater is not limited, and the heater can be used as a heater of the deposition apparatus according to an embodiment as it is configured to perform the above functions.

Subsequently, the internal module IM will be described in detail with reference to FIGS. 3, 4, and 5.

Referring to FIG. 3, the internal module IM may be disposed in the inner space of the external housing HO. The internal module IM may include a first rotation plate RP1, a second rotation plate RP2, a partition PT, a rotation support RS, and an opening OP.

The first rotation plate RP1 and the second rotation plate RP2 may be disposed to face each other, e.g., in parallel to each other. The first rotation plate RP1 and the second rotation plate RP2 may be disposed to be spaced apart from each other at a predetermined interval. The first rotation plate RP1 and the second rotation plate RP2 may have substantially the same shape.

For example, each of the first rotation plate RP1 and the second rotation plate RP2 may have a disk shape. In an embodiment of the external housing HO having a cylindrical shape, a diameter of a front surface, i.e., a diameter of a surface having a circular shape, of each of the first rotation plate RP1 and the second rotation plate RP2 may be smaller than or equal to the diameter of each of the top and bottom surfaces of the external housing HO. The first rotation plate RP1 and the second rotation plate RP2, as will be described later, can be rotated along the rotating rod RR in the external housing HO. In this case, when the diameter of the front surface of each of the first rotation plate RP1 and the second rotation plate RP2 is smaller than or equal to the diameter of each of the top and bottom surfaces of the external housing HO, the first rotation plate RP1 and the second rotation plate RP2 can be smoothly rotated inside the external housing HO.

The rotation support RS may be disposed between the first rotation plate RP1 and the second rotation plate RP2. The rotation support RS can support the first rotation plate RP1 and the second rotation plate RP2 while maintaining a, e.g., constant, distance therebetween.

The rotation support RS may be engaged with the central portion of each of the first rotation plate RP1 and the second rotation plate RP2. In detail, a first end of the rotation support RS may be engaged with the first rotation plate RP1, and a second end of the rotation support RS may be engaged with the second rotation plate RP2.

The rotation support RS may have a cylindrical shape, but the present disclosure is not limited thereto. The rotation support RS may be engaged with the rotating rod RR. In the case where the rotation support RS is engaged with the rotating rod RR, the rotation support RS can be rotated along the rotating rod RR. When the rotation support RS is rotated, the first rotation plate RP1 and the second rotation plate RP2, which are engaged with the rotation support RS, can also be rotated in the same direction along, e.g., around the rotation axis of, the rotating rod RR.

A storage unit for storing the deposition material may be disposed between the first rotation plate RP1 and the second rotation plate RP2. In FIGS. 3 to 5, a case of the deposition material being stored in the inner space defined by the partition PT is illustrated as an example of the storage unit. However, this case should be understood as an example of the storage unit for storing the deposition material, and the structure of the storage unit is not limited by the shape of the partition PT. That is, it should be understood that the storage unit includes all mechanical structures capable of storing the deposition material.

The partition PT may include a side wall SW and an upper cover UC bent and extended from the side wall SW. The side wall SW may be formed to extend in a direction perpendicular to the first rotation plate RP1 and/or the second rotation plate RP2. FIGS. 3 to 5 show a case of the side wall SW extending from the second rotation plate RP2 toward the first rotation plate RP1, but the present disclosure is not limited thereto. That is, in another embodiment, the side wall SW may extend from the first rotation plate RP1, or may extend from the first rotation plate RP1 and the second rotation plate RP2.

The side wall SW may be disposed to be spaced apart from the rotation support RS at a predetermined interval, e.g., the side wall SW may be spaced radially from the rotation support RS. When the side wall SW is disposed to be spaced apart from the rotation support RS at a predetermined interval, a predetermined space may be formed between the side wall SW and the rotation support RS. The space formed between the side wall SW and the rotation support RS may be filled with the deposition material M, as illustrated in FIG. 5.

The deposition material M may be stored in any one state of gas, liquid, and solid, or may be stored in a mixed state of two or more. The deposition material M may be an organic deposition material, but the present disclosure is not limited thereto. In another embodiment, the deposition material M may partially include an inorganic material.

The partition PT may include the upper cover UC bent from the upper end of the side wall SW toward the inside, i.e., bent toward the rotation support RS. The upper cover UC may be formed to be integrated with the side wall SW using the same material, but the present disclosure is not limited thereto. The upper cover UC may also be connected with the side wall SW as an independent structure.

The upper cover UC may be disposed to be bent from one end of the side wall SW toward the inside. FIG. 5 illustrates a case of the upper cover UC and the side wall SW being disposed at a substantially right angle, but the present disclosure is not limited thereto. The upper cover UC may be disposed to be inclined at any suitable predetermined angle with respect to the side wall SW.

A first end of the upper cover UC may be connected to the side wall SW, and a second end of the upper cover UC may face the rotation support RS. The second end of the upper cover UC, which faces the rotation support RS, may be spaced apart from the rotation support RS at a predetermined interval. Hereinafter, the space between the second end of the upper cover UC and the rotation support RS will be referred to as an opening OP. The opening OP can provide communication between the space defined within the partition PT, i.e., a space between the side wall SW and the rotation support RS, and the inner space of the external housing HO.

In an embodiment, at least a part of the deposition material M can exist in a gaseous state. In this case, when the internal module IM is rotated, the gaseous deposition material M can be discharged from the space defined within the partition PT into the inner space of the external housing HO through the opening OP. That is, the width, e.g., radius, of the upper cover UC between its first and second ends may be adjusted to control the width, e.g., radius, of the opening OP, e.g., along the y-axis, to further control discharge amount of the deposition material M through the opening OP.

Hereinafter, the operation of the deposition apparatus according to an embodiment of the present disclosure will be described with reference to FIGS. 6 to 8.

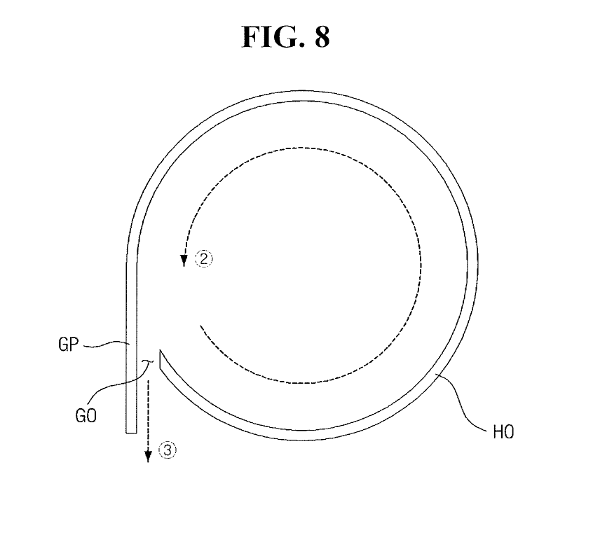

FIG. 6 is a sectional perspective view of the deposition apparatus according to an embodiment of the present disclosure, FIG. 7 is a perspective view of the deposition apparatus according to an embodiment of the present disclosure, and FIG. 8 is a cross-sectional view of a deposition apparatus according to the embodiment of the present disclosure.

Referring to FIG. 6, as described above, the rotating rod RR may be rotated clockwise or counterclockwise. Hereinafter, a case of the rotating rod RR being rotated counterclockwise is exemplified, but the rotation direction of the rotating rod RR is not limited thereto.

When the rotating rod RR is rotated counterclockwise, the internal module IM engaged therewith may also be rotated counterclockwise along with the rotating rod RR. When the internal module IM is rotated, the deposition material M is gathered toward the side wall SW by centrifugal force. When the deposition material M is influenced by centrifugal force, a part of the deposition material M may be discharged to the inner space of the external housing HO through the opening OP (along arrow \textcircled{1} of FIG. 6).

Subsequently, referring to FIGS. 7 and 8, the deposition material M discharged into the inner space of the external housing HO may continue to be rotated counterclockwise (arrows \textcircled{2} of FIGS. 7 and 8). In this case, a part of the deposition material M may be discharged from the inner space of the external housing HO to the outside, i.e., into the chamber CH, through the outlet GO of the external housing HO (arrow \textcircled{3} of FIGS. 7 and 8). The deposition material M discharged through the outlet GO is guided by the guide panel GP, and may proceed toward a target subject, e.g., the substrate S, as described previously with reference to FIG. 1.

When the internal module IM filled with the deposition material M is rotated, centrifugal force is applied to the deposition material M existing in the internal module IM, thereby improving the straightness of the deposition material M, i.e., improving a force, e.g., a flow rate and uniformity, of the deposition material M proceeding toward the substrate S. In addition, the transfer rate of the deposition material M can be improved by the influence of the centrifugal force.

In this case, the deposition material reaches the substrate S, which is a target subject, with sufficient force, so as to easily form a film and reduce the time taken to form the film. That is, a thin film may be formed on the substrate S more rapidly and efficiently, e.g., as compared to thin film deposition via other apparatuses.

Hereinafter, a deposition apparatus according to another embodiment will be described.

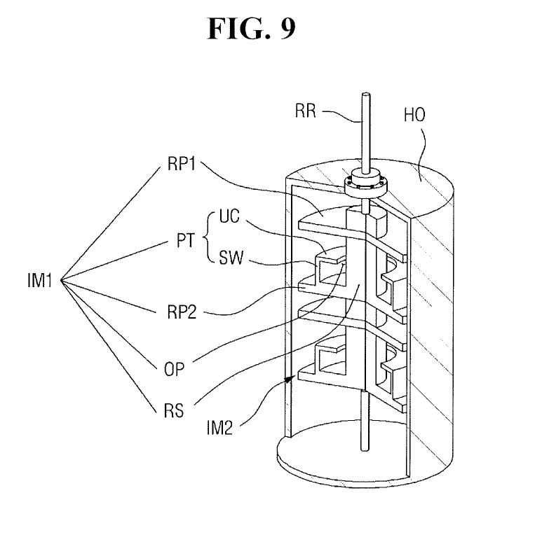

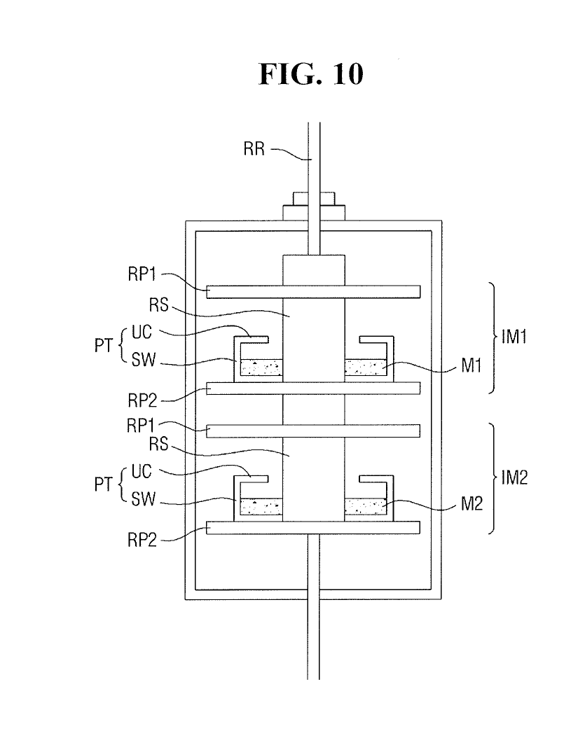

FIG. 9 is a sectional perspective view of a deposition apparatus according to another embodiment of the present disclosure, and FIG. 10 is a longitudinal sectional view of the deposition apparatus of FIG. 9. The deposition apparatus in FIGS. 9-10 is different from the aforementioned deposition apparatus described with reference to FIG. 3 in that it has a plurality of internal modules IM.

In detail, referring to FIGS. 9-10, the deposition apparatus according to another embodiment may have a first internal module IM1 and a second internal module IM2. For convenience of explanation, an embodiment including only two internal modules, i.e., the first internal module IM1 and the second internal module IM2, is described. However, the number of internal modules IM is not limited thereto, e.g., in another embodiment, the number of internal modules IM may be three or more.

The first internal module IM1 and the second internal module IM2 may be substantially the same. That is, the structure and operation of each of the first internal module IM1 and the second internal module IM2 may be substantially the same as the internal module IM described previously with reference to FIGS. 3 to 5. Therefore, detailed descriptions thereof will be omitted.

The first internal module IM1 and the second internal module IM2 may be sequentially disposed along the length direction of the rotating rod RR. That is, the first internal module IM1 and the second internal module IM2 may be superimposed in the length direction thereof. In other words, the rotation support RS of the first internal module IM1 and the rotation support RS of the second internal module IM2 can be completely superimposed, e.g., coextensive along a same axis as the rotating rod RR, in the length direction thereof.

In an embodiment, the first internal module IM1 may be engaged with the second internal module IM2, and the first internal module IM1 and the second internal module IM2 may be engaged with the rotating rod RR. In other word, the first internal module IM1, the second internal module IM2, and the rotating rod RR may be engaged with one another. That is, when the rotating rod RR is rotated, the first internal module IM1 and the second internal module IM2 may also be rotated at the same speed.

In another embodiment, the first internal module IM1 and the second internal module IM2 may be rotated at different speeds. In this case, the first internal module IM1 and the second internal module IM2 may be respectively engaged with different rotating rods. That is, in another embodiment, the deposition apparatus includes one or more rotating rods, and the plurality of internal modules are engaged with different rotating modules to be rotated at different speeds.

In an embodiment, the first internal module IM1 may be filled with a first deposition material M1, and the second internal module IM2 may be filled with a second deposition material M2. In an embodiment, the first deposition material M1 and the second deposition material M2 may be the same material as each other. When the plurality of internal modules store the same deposition material, the flux of the deposition material discharged from the outlet GO may become uniform, e.g., as compared to discharge of a deposition material from a single internal module. In this case, the uniformity of the thin film formed on the substrate S may be improved.

In another embodiment, the first deposition material M1 and the second deposition material M2 may be different from each other. When the first deposition material M1 and the second deposition material M2 are different from each other, the first deposition material M1 and the second deposition material M2 may be mixed in the external housing HO. In the deposition apparatus, the mixture of the first deposition material M1 and the second deposition material M2 is applied onto the substrate S, so as to form a thin film made of the mixture of the first and second deposition materials M1 and M2.

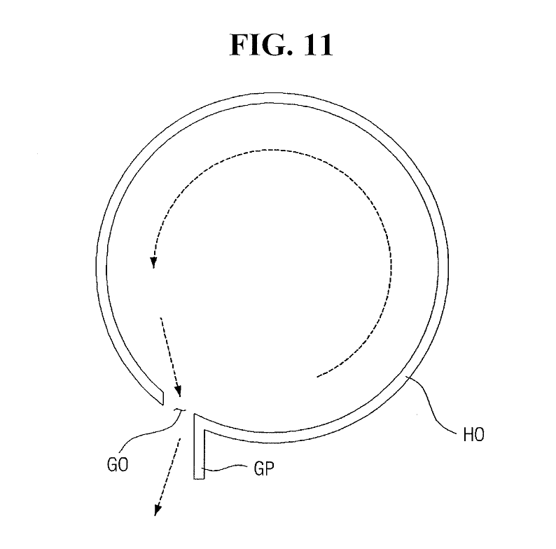

FIG. 11 is a cross-sectional view of the deposition apparatus according to another embodiment of the present disclosure.

Referring to FIG. 11, in the deposition apparatus according to another embodiment of the present disclosure, the guide panel GP may be disposed to face the rotation direction of the deposition material M.

As shown in FIG. 11, when the guide panel GP is disposed to face the rotation direction of the deposition material M, a part of the rotating deposition material M collides with the guide panel GP, and thus this deposition material can be discharged while its proceeding direction is changed. As such, when the guide panel GP is disposed to face the rotation direction of the deposition material M, i.e., the rotation direction of the rotating rod RR, the centrifugal force provided to the deposition material M is reduced, thereby suitably adjusting the force, e.g., flow, of the proceeding deposition material M.

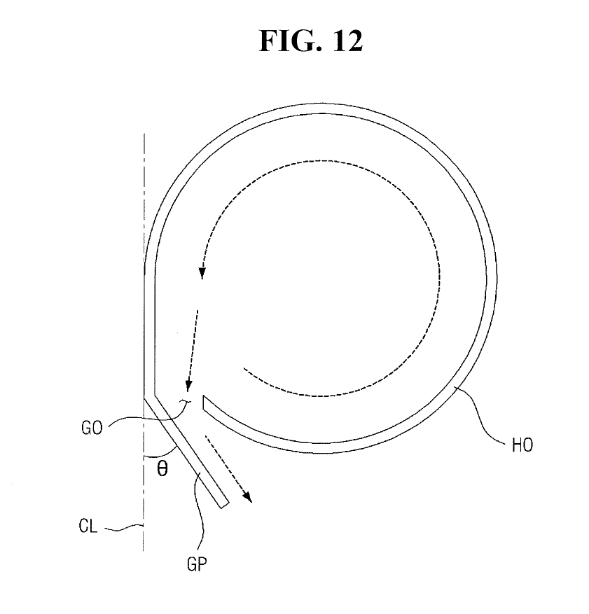

FIG. 12 is a cross-sectional view of a deposition apparatus according to still another embodiment of the present disclosure.

Referring to FIG. 12, the deposition apparatus according to still another embodiment of the present disclosure is different from the aforementioned deposition apparatus described previously with reference to FIG. 2 in that the guide panel GP is disposed to be inclined at a predetermined angle.

In an embodiment, the guide panel GP disposed at least at one side of the outlet GO may be disposed to be inclined at a predetermined angle. For the convenience of explanation, an imaginary tangent line CL in contact with the outer circumference of the external housing HO is defined. The guide panel GP may be inclined at a first angle θ with respect to the tangent line CL. When the guide panel GP is inclined at the first angle θ with respect to the tangent line CL, the proceeding direction of the deposition material may be controlled. That is, the deposition material M is guided by the guide panel GP, and thus this deposition material M may proceed to be inclined at a predetermined angle.

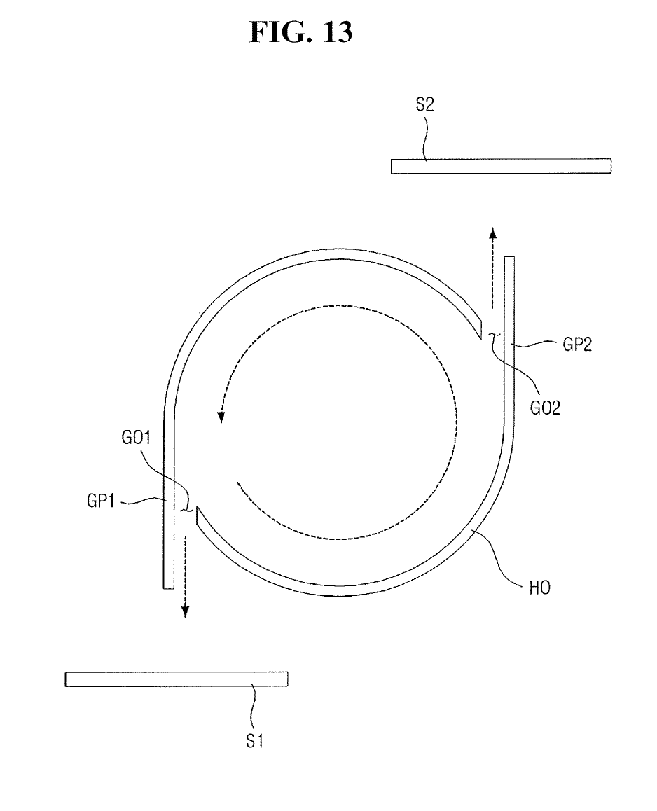

FIG. 13 is a cross-sectional view of a deposition apparatus according to still another embodiment of the present disclosure.

Referring to FIG. 13, the deposition apparatus according to still another embodiment of the present disclosure may have two outlets. For example, the external housing HO may include a first outlet GO1 and a second outlet GO2. In FIG. 13, a case with two outlets, i.e., the first outlet GO1 and the second outlet GO2 disposed in a direction opposite to each other, is described. However, the positions of the first outlet GO1 and the second outlet GO2 are not limited thereto, and the positions thereof may be adjusted as needed in design.

A first substrate S1 may be disposed to face the first outlet GO1, and a second substrate S2 may be disposed to face the second outlet GO2. In this case, film-forming processes may be sequentially or simultaneously performed on the first substrate S1 and the second substrate S2. That is, when the external housing HO has a plurality of outlets, deposition processes are simultaneously performed on several substrates, thereby improving process efficiency and reducing process time.

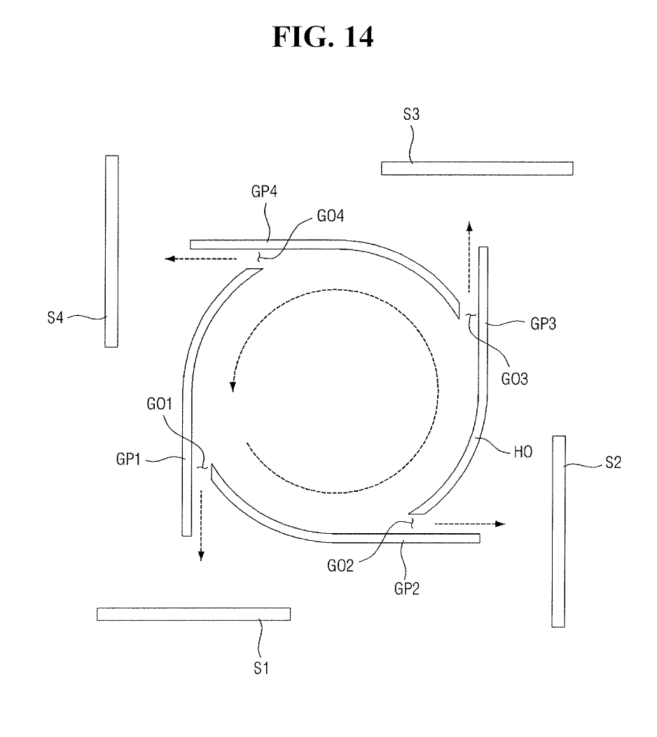

FIG. 14 is a cross-sectional view of a deposition apparatus according to still another embodiment of the present disclosure.

Referring to FIG. 14, the deposition apparatus according to still another embodiment of the present disclosure is different from the aforementioned deposition apparatus described previously with reference to FIG. 13 in the number of its outlets.

That is, as illustrated in FIG. 4, the external housing HO may include four outlets, i.e., a first outlet GO1, a second outlet GO2, a third outlet GO3, and a fourth outlet GO4. In an embodiment, the opening directions of the first outlet GO1 and the second outlet GO2 may be perpendicular to each other, and the opening directions of the first outlet GO1 and the third outlet GO3 may be opposite to each other. That is, the first outlet GO1, the second outlet GO2, the third outlet GO3, and the fourth outlet GO4 may be disposed to be spaced apart from each other at regular intervals along the outer circumference of the external housing HO.

A first substrate S1, a second substrate S2, a third substrate S3, and a fourth substrate S4 may be disposed corresponding to the first outlet GO1, the second outlet GO2, the third outlet GO3, and the fourth outlet GO4. In this case, film-forming processes may be sequentially or simultaneously performed on the first substrate S1, the second substrate S2, the third substrate S3, and the fourth substrate S4. That is, when the external housing HO has a plurality of outlets, deposition processes are simultaneously performed on several substrates, thereby improving process efficiency and reducing process time.

In FIGS. 13 and 14, two or four outlets have been illustrated and described. However, the number of outlets is not limited. In other embodiments, three or five outlets may be used as needed in design.

Hereinafter, a method of manufacturing a display device according to an embodiment of the present disclosure will be described. As an example, the method is described with reference to FIGS. 1 and 6-8.

The method of manufacturing a display device according to an embodiment of the present disclosure includes the steps of providing a deposition source and a substrate S facing the deposition source (FIG. 1), the deposition source including a rotating rod RR, an internal module IM engaged with the rotating rod RR and including a storage unit for storing a deposition material M, and an external housing HO covering the rotating rod RR and the internal module IM and having an outlet GO communicating with ambient air (FIGS. 1 and 6), rotating the rotating rod RR to rotate the internal module IM engaged with the rotating rod RR (FIGS. 6-8), and applying the deposition material M discharged through the outlet GO of the external housing HO onto the substrate S (FIG. 1).

The method of manufacturing a display device according to an embodiment of the present disclosure may be performed by the aforementioned deposition apparatus according to some embodiments of the present disclosure. However, the present disclosure is not limited thereto, and this method may also be performed using a deposition apparatus that is substantially the same as the aforementioned deposition apparatus or uses the same principle.

First, a deposition source and a substrate S facing the deposition source are provided. Here, the deposition source includes the rotating rod RR, the internal module IM engaged with the rotating rod RR and including the storage unit for storing the deposition material M, and the external housing HO covering the rotating rod RR and the internal module IM and having the outlet GO communicating with ambient air.

The rotating rod RR, the internal module IM, and the external housing may be substantially the same as those that have been described in the aforementioned deposition apparatus according to some embodiments. Therefore, detailed descriptions thereof will be omitted.

The substrate S may be disposed to face the deposition source including the rotating rod RR, the internal module IM, and the external housing HO. Subsequently, the rotating rod RR is rotated to rotate the internal module IM engaged with the rotating rod RR. As described in the aforementioned deposition apparatus according to some embodiments of the present disclosure, the rotating rod RR can be integrally rotated with the internal module IM.

When the rotating rod RR is rotated, the deposition material M stored in the storage unit of the internal module IM can be rotated. That is, the rotation of the internal module IM can apply centrifugal force to the deposition material M. A part of the gaseous deposition material M in the internal module IM is discharged to the inner space of the external housing HO while maintaining centrifugal force, and is rotated along the inner wall of the external housing HO.

Subsequently, the deposition material M discharged through the outlet GO of the external housing HO is provided to the substrate S. A part of the deposition material M rotating along the inner wall of the external housing HO may be discharged through the outlet GO. In this case, the centrifugal force applied to the deposition material M acts as a driving force, thereby extruding, e.g., discharging, the deposition material M.

The deposition material M discharged through the outlet GO is guided by the guide panel GP to be provided to the substrate S. This deposition material reaching the substrate S is adhered to the substrate S, so as to form a thin film. When centrifugal force is applied to the deposition material M in this way, the forwarding force of the deposition material M is improved, thereby increasing the efficiency of a deposition process and reducing the process time.

By way of summation and review, a film-forming apparatus evaporating a film-forming material for forming a thin film on a substrate may exhibit a weak transfer force of the film-forming material, e.g., low flow rate of the film-forming material, thereby having a low transfer rate of the evaporated film-forming material onto the substrate, e.g., low deposition rate. In contrast, as described above, a deposition apparatus according to embodiments may have improved straightness of a deposition material. Further, in the deposition apparatus, the transfer rate of a deposition material can be improved. Moreover, in the method of manufacturing a display device, process efficiency can be improved, and process time can be reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing a display device, the method comprising:
providing a deposition source and a substrate facing each other, the deposition source including a rotating rod, an internal module engaged with the rotating rod and having a storage unit for storing a deposition material, and an external housing covering the rotating rod and the internal module and having an outlet communicating with ambient air;
rotating the rotating rod in the deposition source, such that the internal module engaged with the rotating rod is rotated; and
applying the deposition material discharged through the outlet of the external housing onto the substrate.

2. The method as claimed in claim 1, wherein a centrifugal force is provided to the deposition material by the rotation of the internal module.

3. The method as claimed in claim 1, wherein a plurality of internal modules are provided in a single deposition source, such that the plurality of internal modules are rotated in a same direction as the rotating rod.

4. The method as claimed in claim 1, wherein the external housing has a cylindrical shape.

5. The method as claimed in claim 1, wherein the external housing and the rotating rod are rotatably engaged with each other.

6. The method as claimed in claim 1, wherein the deposition source further comprises a guide panel formed at least at one side of the outlet.

7. The method as claimed in claim 1, wherein the internal module includes a first rotation plate and a second rotating plate, which are disposed to be spaced apart from each other at a predetermined interval.

8. The method as claimed in claim 7, wherein the deposition source further comprises a rotation support formed between the first rotation plate and the second rotation plate.

9. The method as claimed in claim 8, wherein the internal module further comprises a side wall extended in a direction parallel to the rotating rod and an upper cover bent and extended from the side wall, a first end of the upper cover being connected to the sidewall, and a second end of the upper cover being spaced apart from the rotation support at a predetermined interval.

10. The method as claimed in claim 1, wherein the internal module includes a partition, and the deposition material is stored in a space defined by the partition.

11. The method as claimed in claim 10, wherein the partition includes a side wall extended in a direction parallel to the rotating rod and an upper cover bent and extended from one end of the side wall.

12. The method as claimed in claim 1, wherein a plurality of internal modules are provided in the deposition source, and the plurality of internal modules are superimposed along a length direction of the rotating rod.

13. The method as claimed in claim 12, wherein the plurality of internal modules includes a first internal module and a second internal module, the first internal module storing a first deposition material, and the second internal module storing a second deposition material different from the first deposition material.

14. The method as claimed in claim 1, wherein the external housing includes a plurality of outlets, and the plurality of outlets have opening directions different from each other.

15. The method as claimed in claim 1, wherein a plurality of internal modules are provided, and the plurality of internal modules are rotated in a same direction as the rotating rod.

16. The method as claimed in claim 15, wherein the plurality of internal modules includes a first internal module and a second internal module, and the first internal module and the second internal module are rotated at different speeds from each other.
